(19) United States
(12) Patent Application Publication
(10) Pub. No.: US 2018/0371312 A1
(43) Pub. Date: Dec. 27, 2018

(54) CONVERSION ELEMENT, OPTOELECTRONIC COMPONENT PROVIDED THEREWITH, AND METHOD FOR MANUFACTURING A CONVERSION ELEMENT

(71) Applicant: OSRAM Opto Semiconductors GmbH, Regensburg (DE)

(72) Inventor: Georg DIRSCHERL, Tegernheim (DE)

(21) Appl. No.: 15/777,895

(22) PCT Filed: Dec. 1, 2016
(86) PCT No.: PCT/EP2016/079462

§ 371 Date: May 21, 2018

(30) Foreign Application Priority Data
Dec. 14, 2015 (DE) 10 2015 121 720.1

(51) Int. Cl. C09K 11/02; C09K 11/08; H01L 33/50

(52) U.S. Cl. CPC C09K 11/025; B82Y 20/00; H01L 33/502; C09K 11/08

(57) ABSTRACT

The invention relates to a conversion element (4) comprising quantum dots (1) designed to convert the wavelength of radiation; each of the quantum dots (1) has a surface (1d), and at least two surfaces (1d) of adjacent quantum dots (1) are connected via at least one linker (7), provided for keeping the quantum dots (1) at a distance from each other, such that a network of quantum dots (1) and linkers (7) is formed.

The invention relates to a conversion element. The invention further relates to an optoelectronic component, which in particular comprises a conversion element. The invention further relates to a method for producing a conversion element.

Conversion elements often have conversion materials, for example quantum dots. The conversion materials convert the radiation emitted by a radiation source into a radiation having a changed, for example longer wavelength. The conversion materials are generally dispersed into a polymer-based matrix material, in order to obtain the conversion material in a processable form. Polymer-based matrix materials, however, have the disadvantage that they are permeable to moisture and/or oxygen and/or acidic gases from the environment. Furthermore, polymer-based matrix materials have a low aging stability. Secondly, a homogeneous and controllable distribution of the conversion materials in the matrix material is difficult to achieve.

The aim of the invention is to provide a conversion element which has improved properties. In particular, a conversion element is to be provided which is free of a polymer as a matrix material and thus has a high aging stability. In addition, the conversion element should have a high efficiency. The invention further relates to an optoelectronic component having improved properties. The invention further relates to a method for producing a conversion element which generates a conversion element having improved properties.

These objects are achieved by a conversion element according to independent claim 1. Advantageous embodiments and developments of the invention are the subject matter of dependent claims 2 to 12. Furthermore, these objects are achieved by an optoelectronic component according to claim 13. Furthermore, these objects are achieved by a method for producing a conversion element according to claim 14. Advantageous embodiments and developments of the method are the subject matter of dependent claims 15 to 17.

In at least one embodiment, the conversion element comprises quantum dots. The quantum dots are designed for wavelength conversion of radiation. The quantum dots each have a surface. At least two surfaces of quantum dots, in particular adjacent quantum dots, are connected to one another at least via a linker. The linker serves for spacing the quantum dots. A network of quantum dots and linkers is thus formed. In particular, the network is a two-dimensional and/or three-dimensional network. The term “network” is understood here and below such that the quantum dots form the so-called node points of the network and the linkers form the connecting lines between the quantum dots. In particular, the quantum dots and the linkers are connected to one another via chemical bonds, in particular via covalent and/or coordinative bonds.

According to at least one embodiment of the conversion element, the conversion element comprises quantum dots or consists thereof. The quantum dots are designed for wavelength conversion.

The wavelength-converting quantum dots are, in particular, a sensitive conversion material, that is to say a conversion material which is sensitive to oxygen, moisture and/or acid gases. Preferably, the quantum dots are nanoparticles, that is to say particles having a size in the nanometer range with a particle diameter d₅₀ for example of between at least 1 nm and at most 1000 nm. The quantum dots comprise a semiconductor core having wavelength-converting properties. In particular, the core of the quantum dots consists of a II/IV or III/V semiconductor. For example, the quantum dots are selected from a group consisiting of InP, CdS, CdSe, InGaAs, GaInP and CuInSe₂. The semiconductor core can be surrounded by one or more layers as a coating. The coating can be organic and/or inorganic. In other words, the semiconductor core can be completely or almost completely covered by further layers on the outer surface or surface.

The semiconductor core can be a monocrystalline or polycrystalline agglomerate.

According to at least one embodiment, the quantum dots have an average diameter of 3 to 10 nm, particularly preferably of 3 to 5 nm. By varying the size of the quantum dots, the wavelength of the converting radiation can be varied in a targeted manner and can thus be correspondingly adapted for respective applications. The quantum dots can be spherical or shaped in the shape of a rod.

A first encasing or sheathing layer of a quantum dot is, for example, coated with an inorganic material, such as, for example, zinc sulphide, cadmium sulfide and/or cadmium selenide, and serves to generate the quantum dot potential. The first sheathing layer and the semiconductor core can be almost completely enclosed by at least one second sheathing layer on the exposed surface. In particular, the first sheathing layer is an inorganic ligand shell, which in particular has an average diameter, including the semiconductor core, of 1 to 10 nm. The second sheathing layer can, for example, be filled with an organic material, such as cystamine or cysteine, and sometimes serves to improve the solubility of the quantum dots in, for example, a matrix material and/or a solvent. In this case, it is possible for a spatially uniform distribution of the quantum dots in a matrix material to be improved on account of the second covering layer. The matrix material can be formed, for example, with at least one of the following substances: acrylate, silicone, hybrid material, such as ormocer, for example ormoclear, polydimethylsiloxane (PDMS), polydivinylsiloxane, for example from PLT, Pacific Light Technologies, or mixtures thereof.

Acrylic-functionalized quantum dots, such as ormoclear, can be obtained, for example, from the company nanoco.

When the quantum dots are dispersed into an inorganic or organic matrix material, this often gives rise to the problem that the matrix material is not very stable. In addition, the mixture is a transparent two-component mixture. Furthermore, the matrix material is permeable to moisture and environmental influences, for example acidic gases. In addition, an optimum distance between the individual quantum dots cannot be adjusted sufficiently, so that quenching of the emitted radiation is increased. This leads to losses in the efficiency of the conversion element.

Alternatively, quantum dot sol or quantum dot dispersions can be used to produce a conversion element. In this case, the solvent of the quantum dot dispersion, i.e. a mixture of quantum dots and solvent, is extracted and determines the quantum efficiency for this purpose. However, this is very small, since the distance of the individual quantum dots to one another is low on account of the quantum dot agglomeration formation. As a result, the emission of the quantum dots is partially or completely cancelled, i.e. quenched.

The quantum dots of the conversion element each have a surface. The surface can be the surface of the semiconductor core. Alternatively, the surface can also be the surface of the first sheathing layer or of a further sheathing layer, for example of the second sheathing layer. At least two surfaces, in particular more than two surfaces, of adjacent quantum dots are connected to one another at least via a linker or a plurality of linkers. A linker or spacer is understood here and hereinafter to be a molecular compound which is arranged between at least two surfaces of the quantum dots, in particular covalently and/or coordinatively bonded to the surfaces of the quantum dots, and which thus separates the quantum dots from one another.

According to at least one embodiment, the quantum dots are selected from a group consisting of InP, CdS, CdSe and CuInSe₂ and/or are free of an inorganic or organic coating. In other words, the quantum dots then do not have a further enveloping or sheathing layer except for the semiconductor core.

According to at least one embodiment, the distance between adjacent quantum dots is at least 20 nm, 15 nm, 14 nm, 13 nm, 12 nm, 11 nm, 10 nm, 9 nm, 8 nm or 7 nm and/or at most 30 nm, 40 nm, 50 nm, 100 nm. Quenching of the emission is thus reduced or prevented. The distance between adjacent quantum dots can be set, for example, by the chain length of the linker.

The linker chemically binds to the surface of the respective quantum dot. In particular, the chemical connection of the linker to the surface of the respective quantum dot is covalent and/or coordinative. According to at least one embodiment, the linker has at least two reactive groups. The reactive groups are each arranged terminally on the linker. The reactive groups bind in particular to the respective surface of the corresponding quantum dot covalently and/or coordinatively.

According to at least one embodiment, the reactive group is a phosphonate group and/or sulfate group. In other words, the linkers or spacers can each have a reactive group at their side chain ends. The reactive groups can be separated from one another by alkyl groups or alkene groups having a corresponding chain length.

According to at least one embodiment, the linker is formed from at least two pre-linkers. Each of the pre-linkers has a functional group. The functional group can be cross-linked or hydrosilylatable. The linker can thus be produced after the cross-linking or hydrosilylating of the two pre-linkers or is produced by cross-linking or hydrosilylating. In other words, the quantum dots have a pre-linker during the production of the conversion element. The pre-linker has at one chain end a reactive group, for example a phosphonate group. Said phosphonate group binds covalently and/or coordinatively to the corresponding surface of the respective quantum dot. A functional group is arranged at the free chain end of the corresponding pre-linker. The functional group is, for example, a vinyl group, acryl group and/or Si—H group. The functional group of the respective pre-linker, which is connected to the corresponding surface of the respective quantum dot, is covalently bonded to a second pre-linker via the functional group thereof, for example by polymerization or hydrosilylation. The polymerization can be, for example, radical, cationic or anionic polymerization. The linker is thus produced from two pre-linkers by connecting the pre-linkers via their functional groups.

According to at least one embodiment, the conversion element is free of an inorganic and/or organic matrix material. In other words, the conversion element has no matrix material, in particular polymer-based matrix material. It is therefore possible to dispense with the matrix material, since the respective quantum dots are chemically bonded to one another via the linkers.

According to at least one embodiment, the linker has a carbon chain having at least 32 carbon atoms, in particular between 32 carbon atoms and at most 40 carbon atoms inclusive. Alternatively or additionally, the linker can have a silyl chain with at least 32 carbon atoms inclusive and/or at most 40 carbon atoms inclusive.

Alternatively or additionally, the linker can have a carbon chain, for example as described above, which additionally has ester groups and/or aromatic groups in the carbon chain. Alternatively or additionally, the linker can have a silyl chain, for example as described above, which additionally contains ester groups, H, alkoxy, —OMe, —O—CH2-CH3,

—O—CH2-CH2-CH3 and/or aromatic groups in the silyl chain. In particular, the corresponding carbon chains and/or silyl chains are arranged between the two reactive groups of the linker. Accordingly, the pre-linker can have at least one carbon chain with at least 16 carbon atoms up to 20 carbon atoms inclusive. Alternatively or additionally, the pre-linker can have a silyl chain with at least 16 silicon atoms and/or at most 20 silicon atoms. In this way, a distance between the quantum dots can be generated, which reduces or prevents quenching of the converting radiation.

Alternatively or additionally, the linker can be PDMS (polydimethylsiloxane), PDPS (polydiphenylsiloxane), polydimethylsiloxane chains or polydiphenylsiloxane chains, wherein the chains can be substituted by methyl and/or phenyl side groups.

According to at least one embodiment, the pre-linker has the formula C═C—(SiR₂—O)n-PO(OH)₂ where n=16, 17, 18 or 20 and

R=CH₃ and/or phenyl.

According to at least one embodiment, the carbon chain and/or silyl chain additionally have/has side chains, which are selected from: H, alkoxy, —O—CH2-CH3, —O—CH2-CH2-CH3, methyl (Me), phenyl (Ph), O-Me, O-Ph.

According to at least one embodiment, the functional group is crosslinkable or hydrosilylatable. In other words, the functional group is cross-linked and/or hydrosilylated during the production of the conversion element. Alternatively or additionally, the functional group is selected from a group consisting of vinyl, allyl, haloallyl, acrylate, methacrylate, Si—H and epoxy.

According to at least one embodiment, the conversion element is a single-phase system or a one-phase system. In other words, the quantum dots which are connected to one another via the linkers form only one phase. In this way, no miscibility problems are generated, as is the case, for example, in a system consisting of quantum dots dispersed in conventional matrix materials.

According to at least one embodiment, the surface of a respective quantum dot or at least 80% of the surface has at least three and at most five linkers, which are bound covalently or coordinatively to the surface of the quantum dot.

The inventor has recognized that owing to the chemical connection of the quantum dots via bimodal linkers, i.e. linkers with at least two reactive groups, an additional inorganic and/or organic matrix material can be dispensed with. The necessary distance between adjacent quantum dots can also be set by the chain length of the corresponding linker, thereby preventing quenching of the emission. Furthermore, short chains of the linker, for example chains having a chain length of 16 to 20 atoms, can be used, which leads to a maximization of the inorganic content, which leads to an increase in the blue light component of the emitted radiation and to temperature stability. A lower organic proportion reduces the susceptibility to yellowing of the conversion element. Long chains of the linker, for example chains having a chain length of >20 atoms, can adjust the polymer-like toughness.

Furthermore, there is no scattering at the interfaces between a quantum dot and the matrix material by means of the conversion element, as described in conventional conversion elements, so that the conversion element has a high transparency.

Furthermore, a conversion element can be provided which has a high filling level of quantum dots. The higher the filling level of the quantum dots, the thinner the conversion element can be produced. In particular, the layer thickness of a conversion element formed as a layer can range from 1 to 5 μm. In addition to the design freedom, a thinner layer of the conversion element also provides better heat dissipation and therefore protects, in particular, temperature-labile quantum dots.

Furthermore, no macrophase separation is observed by the conversion element described here, since this is a single-phase system and not a two-phase system comprising a quantum dot and an inorganic or organic matrix material with an increase in the filling level.

The invention further relates to an optoelectronic component. In particular, the optoelectronic component has a conversion element described here. This means that all the features disclosed for the conversion element are also disclosed for the optoelectronic component and vice versa.

According to at least one embodiment, the optoelectronic component comprises a conversion element and a semiconductor layer sequence. The semiconductor layer sequence is capable of emitting radiation. The conversion element is arranged in the beam path of the semiconductor layer sequence and converts the radiation emitted by the semiconductor layer sequence into radiation of altered wavelength during operation. The conversion of the radiation emitted by the semiconductor layer sequence, for example from the blue spectral region, into radiation of altered wavelength, for example in the red or green spectral range, can be complete or partial. In the case of partial conversion, mixed-colored light, in particular white light, can be generated.

According to at least one embodiment, the optoelectronic component is a light-emitting diode, LED for short. The optoelectronic component is then preferably designed to emit blue or white light.

The optoelectronic component comprises at least one optoelectronic semiconductor chip which has the semiconductor layer sequence. The semiconductor layer sequence of the semiconductor chip is preferably based on a III-V compound semiconductor material. The semiconductor material is preferably a nitride compound semiconductor material, such as AlₙIn₁₋ₙ₋ₘGaₘN, or else a phosphide compound semiconductor material, such as AlₙIn₁₋ₙ₋ₘGaₘP, wherein in each case

0≤n≤1, 0≤m≤1 and n+m≤1. The semiconductor material can likewise be AlₓGa₁₋ₓAs where 0≤x≤1. In this case, the semiconductor layer sequence can have dopants and additional constituents. For the sake of simplicity, however, only the essential components of the crystal lattice of the semiconductor layer sequence, i.e. Al, As, Ga, In, N or P, are indicated, even if these can be partially replaced and/or supplemented by small quantities of further substances.

The semiconductor layer sequence comprises an active layer having at least one pn-junction and/or having one or more quantum well structures. During operation of the LED or of the semiconductor chip, an electromagnetic radiation is generated in the active layer. A wavelength or a wavelength maximum of the radiation is preferably in the ultraviolet and/or visible and/or infrared spectral range, in particular lying at wavelengths between 420 nm and 800 nm inclusive, for example between 440 nm and 480 nm inclusive.

The conversion element is arranged in the beam path of the semiconductor layer sequence. The conversion element converts, in particular, the UV radiation emitted by the semiconductor layer sequence, IR or visible radiation into radiation with altered, for example longer wavelength, for example into red, green or orange-colored light completely or partially.

According to at least one embodiment, the conversion element is arranged directly on the semiconductor layer sequence of the semiconductor chip. Here and in the following, reference is made to the fact that the conversion element is applied directly, that is to say that no further layers or elements are arranged between the semiconductor layer sequence and the conversion element. This does not exclude that a connecting element, such as an adhesive, is arranged between the semiconductor layer sequence and the conversion element.

Alternatively, the conversion element can also be spaced apart from the semiconductor chip. In this case, further elements or layers can then be arranged between the semiconductor layer sequence and the conversion element. For example, adhesive layers can be used as further layers.

The invention further relates to a method for producing a conversion element. The conversion element described above is preferably produced using the method. This means that all the features disclosed for the conversion element are also disclosed for the method for producing a conversion element and vice versa. The same also applies to the optoelectronic component, which in particular comprises a conversion element as described above.

According to at least one embodiment, the method for producing a conversion element comprises the steps of:

A) providing at least two quantum dots, in particular more than two quantum dots, each of which has a surface,

B) functionalizing the at least two surfaces with in each case one pre-linker, wherein the respective pre-linker is directly or coordinatively linked to the surface of the respective quantum dot, wherein the pre-linker has a functional group at its end,

C) activating of the functional group, so that at least two or exactly two pre-linkers are connected to one another and form a linker, which connects the two surfaces of the quantum dots to one another, so that the linker and the quantum dots form a network.

According to at least one embodiment, step C) is carried out by means of an initiator, by means of UV radiation or thermally. Lucirin TPO-L, for example, can be used as an initiator. Alternatively, the functional groups can also be activated thermally, for example at a temperature of 60° C. to 180° C.

According to at least one embodiment, the pre-linker has a carbon chain with at least 16 carbon atoms and/or at most 20 carbon atoms, each of which has a phosphonate group or sulfate group as a reactive group and a functional group. The carbon chain binds directly via the phosphonate group and/or sulfate group to the surface of a quantum dot. Via the functional group, the carbon chain is chemically connected, in particular covalently bonded, to a further pre-linker of an adjacent surface of a further quantum dot. The covalent bonding can be carried out by hydrosilylation or polymerisation, for example by radical polymerisation.

According to at least one embodiment, the pre-linker has a silyl chain with at least 16 silicon atoms and/or at most 20 silicon atoms. At the end of the silyl chain, in each case one phosphonate group or sulfate group is arranged as a reactive group and one functional group is arranged. The silyl chain can be directly connected to the surface of a quantum dot via the phosphonate group or sulfate group. In particular, the silyl chain is connected via the functional group to a further pre-linker of an adjacent surface of a further quantum dot. The connection between the functional groups can be carried out by polymerization, that is to say crosslinking, or hydrosilylation.

Further advantages, advantageous embodiments and developments will become apparent from the exemplary embodiments described below in conjunction with the figures.

In the figures:

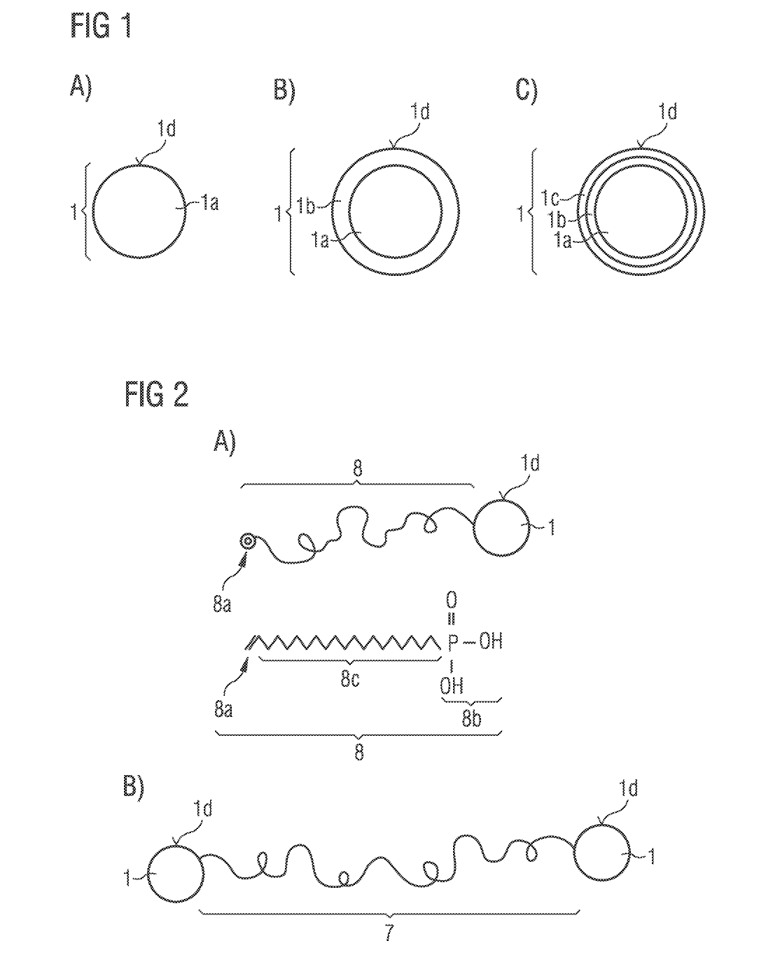

FIGS. 1A to 1C each show quantum dots according to one embodiment,

FIGS. 2A and 2B each show a conversion element according to an embodiment,

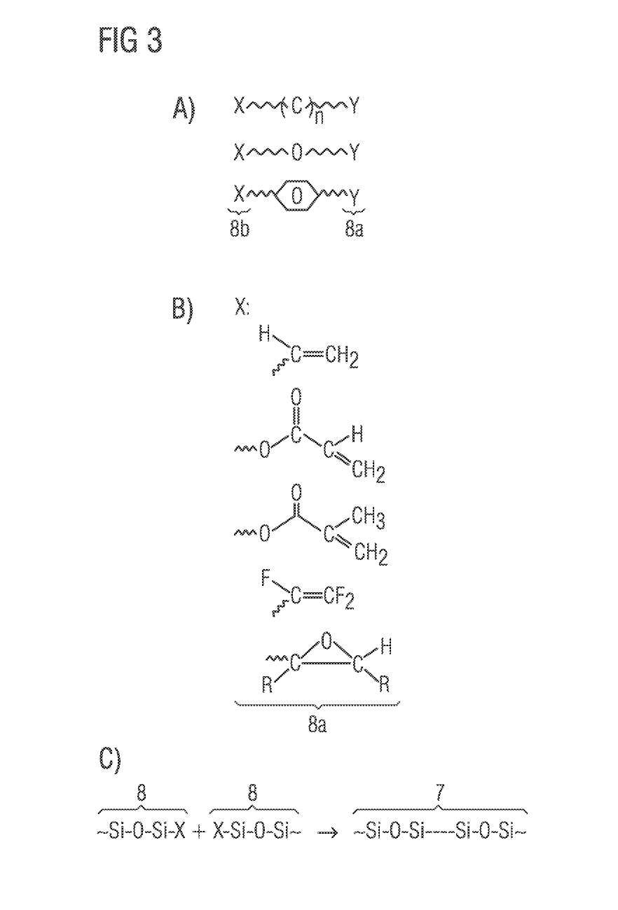

FIGS. 3A to 3C each show a conversion element according to an embodiment,

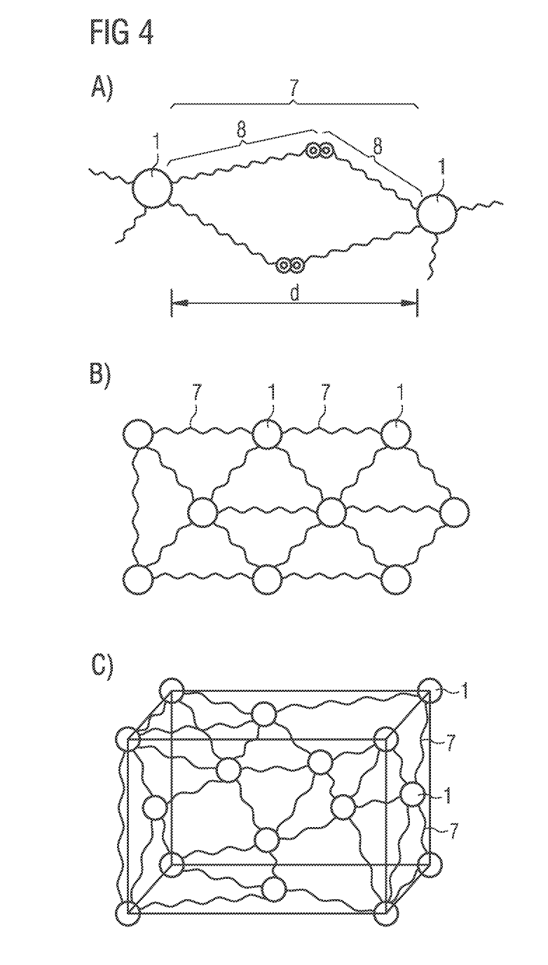

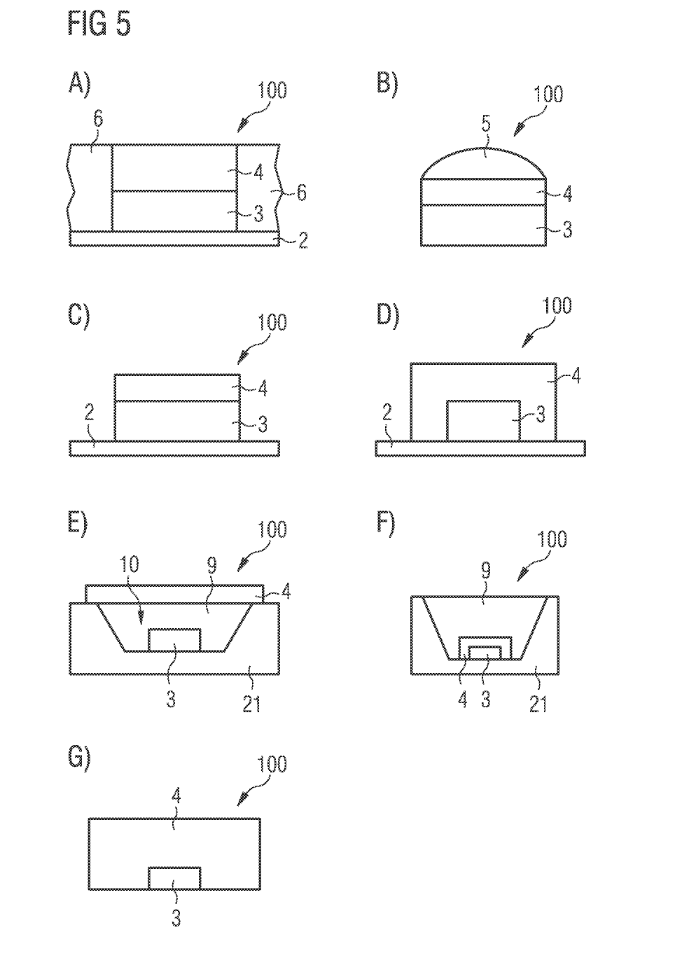

FIGS. 4A to 4C each show a conversion element according to an embodiment and

FIGS. 5A to 5G each show a schematic sectional illustration of an optoelectronic component according to an embodiment.

In the exemplary embodiments and figures, identical or identically acting elements can in each case be provided with the same reference symbols. The elements illustrated and their size relationships among one another are not to be regarded as true to scale. Rather, individual elements, such as, for example, layers, components and regions, are represented with an exaggerated size for better representability and/or for a better understanding.

FIGS. 1A to 1C each show a schematic side view of a quantum dot according to an embodiment. As shown in FIG. 1A, the quantum dot 1 can comprise or consist of a semiconductor core 1a. If the quantum dot 1 consists of a semiconductor core 1a or comprises the latter, the surface 1d of the quantum dot 1 is then the outer surface or surface of the semiconductor core 1a. The semiconductor core 1a can have wavelength-converting properties. The semiconductor core 1a can be formed, for example, from cadmium selenide, cadmium sulfide, indium phosphide and copper indium selenide. The quantum dot 1 can be free of a further coating, for example an inorganic and/or organic coating, as shown in FIGS. 1B and 1C.

FIG. 1B shows a quantum dot 1 which, in addition to the semiconductor core 1a, has an enveloping or sheathing first layer 1b. The enveloping first layer 1b can, for example, be formed from zinc sulphide. The quantum dot 1 can have an average diameter of 1 to 10 nm. In comparison thereto, the quantum dot 1 of FIG. 1A can have an average diameter of 5 nm.

FIG. 1C shows a quantum dot 1 which can additionally have a further second enveloping or sheathing layer 1c in addition to the semiconductor core 1a and the first sheathing layer 1b. The further enveloping layer 1c can be an organic coating, for example made of silicone, acrylate or a mixture thereof. If the surface 1d of a respective quantum dot 1 is discussed, this then corresponds to the surface of the first enveloping layer 1b according to FIG. 1B and to the surface of the second enveloping layer 1c according to FIG. 1C.

FIGS. 2A and 2B each show a schematic side view of a conversion element according to an embodiment. FIG. 2A shows a quantum dot 1 to which a pre-linker 8 is connected. The pre-linker 8 has a reactive group 8b, in this case a reactive phosphonate group. The reactive group 8b can bind covalently and/or coordinatively to the surface 1d of the quantum dot 1. The pre-linker 8 also has a functional group 8a. The functional group 8a can be, for example, vinyl, allyl, haloallyl, acrylate, methacrylate, Si—H and/or epoxy. A chain 8c is arranged between the functional group 8a and the reactive group 8b, in this example a carbon chain having 18 carbon atoms. A vinyl group is shown here by way of example as the functional group 8a.

FIG. 2B shows two quantum dots 1, which are connected to one another via a linker 7 for spacing. The linker 7 has two reactive groups 7a at the chain ends (not shown here). The reactive groups 7a, which are, for example, a phosphonate group or sulfate group, are bound to the surface 1d of the respective quantum dot 1. The linker 7 has a chain between the reactive groups 7a. The chain can, for example, be a carbon chain and/or a silyl chain. In addition, ether groups and/or aromatic units may be part of the chain. A defined distance between the corresponding quantum dots 1 can thus be generated by the linker 7. In particular, the distance is less than or equal to 10 nm, for example 7 nm.

FIG. 3A shows a possible chain of a linker 7 or pre-linker 8. For example, the linker 7 can be a carbon chain. Furthermore, the carbon chain can additionally have one or more ether groups and/or aromatic groups. At the side ends, the pre-linker 8 has a functional group X, 8b. The functional group X, 8b can be a vinyl, acrylate, methacrylate, halogenated, i.e. in particular fluorinated, allyl group or epoxy group. At the other end of the respective chain of the pre-linker 8 or linker 7, the latter can have a reactive group Y, 8a, which is, for example, a phosphonate or sulfate group.

FIG. 3C shows the reaction of two pre-linkers 8 to form? a linker 7, wherein the functional groups X of the corresponding pre-linkers 8 react with one another and form a linker 7, wherein the functional groups X are crosslinked or hydrosilylated and a covalent bond is formed between the pre-linkers 8.

FIG. 4A shows a conversion element, in particular a schematic view of the connection of the quantum dots 1 to pre-linkers 8. In this embodiment, two quantum dots 1 are connected via two pre-linkers 8, i.e. a total of four pre-linkers 8 are linked covalently and/or coordinatively to one another. In this case, a distance d between the quantum dots 1 of at least 10 nm, for example 15 nm, is produced.

FIG. 4B shows a two-dimensional network of quantum dots 1 and linkers 7, wherein the quantum dots 1 form the corresponding nodes of the network and the linkers 7 form the connecting lines between the nodes or quantum dots 1.

FIG. 4C shows a three-dimensional network of quantum dots 1 and linkers 7.

FIGS. 5A to 5G show schematic side views of optoelectronic components 100 according to various embodiments. In particular, the optoelectronic component is a light-emitting diode, for short LED. According to FIG. 5A, the light source 3 is a light-emitting diode chip which is applied to a carrier 2. Directly above the light-emitting diode chip 3, the conversion element 4 is located. This does not exclude that a connecting element, such as an adhesive, is arranged between the respective components. Optionally, the light source 3 and the conversion element 4 are laterally surrounded by a reflector casting 6.

In the exemplary embodiment as shown in FIG. 5B, the optoelectronic component 100 additionally has a lens 5. The lens 5 can be arranged directly downstream of the conversion element 4.

In FIG. 5C it can be seen that the conversion element 4 is arranged directly on the light-emitting diode chip or is arranged on the semiconductor layer sequence 3 of the optoelectronic component 100. In this case, the reflector casting 6 is absent in comparison to FIG. 5A.

In the exemplary embodiment as shown in FIG. 5B, the conversion element 4 surrounds the entire surface of the semiconductor chip or the light source 3. In particular, the conversion element 4 has a constant thickness around the light source 3.

According to FIG. 5E, the light source or the semiconductor chip 3 is arranged in a recess 10 of an optoelectronic component 100. The recess 10 can be filled with a potting 9, for example made of silicone. The conversion element 4 is arranged directly downstream of the potting 9. The optoelectronic component 100 further comprises a housing 21. In other words, the conversion element is spatially separated from the light source.

FIG. 5F shows that the conversion element 4 surrounds the semiconductor chip or light source 3 in a cap-like manner, as a result of which the conversion element 4 has a uniform thickness in all directions. The conversion element 4 and the light source 3 can be arranged in a recess of a housing 21 of an optoelectronic component 100 and can be surrounded by a potting 9.

The exemplary embodiment of FIG. 5G shows an optoelectronic component 100 in which the conversion element 4 surrounds the light source 3, i.e. on its entire surfaces, in a form-fitting and material-to-material manner.

The exemplary embodiments described in conjunction with the figures and the features thereof can also be combined with one another in accordance with further exemplary embodiments, even if such combinations are not explicitly shown in the figures. Furthermore, the exemplary embodiments described in conjunction with the figures can have additional or alternative features according to the description in the general part.

The invention is not restricted to the exemplary embodiments by the description on the basis of the exemplary embodiments. Rather, the invention encompasses any new feature and also any combination of features, which includes in particular any combination of features in the patent claims, even if this feature or this combination itself is not explicitly specified in the patent claims or exemplary embodiments.

This patent application claims the priority of German patent application 10 2015 121 720.1, the disclosure content of which is hereby incorporated by reference.

### REFERENCES

100 optoelectronic component
D distance
1 quantum dot or quantum dots
1a semiconductor core
1b first sheathing layer
1c second sheathing layer
1d surface of the quantum dot
2 support
3 semiconductor chip, semiconductor layer sequence, light source
4 conversion element
5 lens
6 reflection potting
7 linker
7a reactive group
8 pre-linker
8a reactive group
8b functional group
8c carbon chain and/or silyl chain
9 potting
10 recess
21 housing

1. A conversion element comprising
quantum dots, which are designed for wavelength conversion of radiation,
wherein the quantum dots each have a surface, wherein at least two surfaces of adjacent quantum dots have at least one linker for spacing the quantum dots, such that a network of quantum dots and linkers is formed,
wherein the linker has at least two reactive groups, each of which is covalently or coordinatively bound on the respective surface of the quantum dot.

2. (canceled)

3. The conversion element according to claim 1,
wherein the reactive group is a phosphonate group or sulfate group.

4. The conversion element according to claim 1,
wherein the linker is formed from at least two pre-linkers, wherein each pre-linker has a functional group which can be cross-linked or hydrosilylatable, so that after the cross-linking or hydrosilylation of the two pre-linkers the linker is formed.

5. The conversion element according to claim 1,
wherein the conversion element is free of an inorganic and/or organic matrix material.

6. The conversion element according to claim 1,
wherein the distance (d) between adjacent quantum dots is at least 10 nm.

7. The conversion element according to claim 1,
wherein the linker comprises a:
a) carbon chain having at least 32 carbon atoms,
b) silyl chain having at least 32 carbon atoms,
c) carbon chain having ester groups in the carbon chain,
d) carbon chain having aromatic groups in the carbon chain,
e) silyl chain with ester groups in the silyl chain, or
f) silyl chain having aromatic groups in the silyl chain,
g) polydimethylsiloxane chain or polydiphenylsiloxane chain,
wherein the respective chain a) to g) is arranged between the two reactive groups.

8. The conversion element according to claim 1,
wherein the carbon chain and/or silyl chain additionally comprises side chains, which are selected from: H, alkoxy, —OMe, —O—CH₂—CH₃, —O—CH₂—CH₂—CH₃.

9. The conversion element according to claim 1,
wherein the functional group can be cross-linked or hydrosilylatable and is selected from a group consisting of vinyl, allyl, haloallyl, acrylate, methacrylate, Si—H and epoxy.

10. The conversion element according to claim 1,
wherein the quantum dots are selected from a group consisting of InP, CdS, CdSe and CuInSe₂ and/or wherein the quantum dots are free of an inorganic or organic coating.

11. The conversion element according to claim 1,
wherein the conversion element is a single-phase system.

12. The conversion element according to claim 1,
wherein at least three and at most five linkers are linked covalently or coordinatively to a surface of a quantum dot.

13. An optoelectronic component with a conversion element according to claim 1 comprising:
a semiconductor layer sequence which is capable of emitting radiation,
wherein the conversion element is arranged in the beam path of the semiconductor layer sequence and converts during operation the radiation emitted by the semiconductor layer sequence into radiation having a changed wavelength.

14. A method for producing a conversion element according to claim 1 comprising the steps of:
A) providing at least two quantum dots, each having a surface,
B) functionalizing the at least two surfaces with in each case one pre-linker,
wherein the respective pre-linker is directly covalently or coordinatively linked to the surface of the respective quantum dot, wherein the pre-linker has a functional group at its end,
c) activating the functional group, such that the at least two pre-linkers are connected to one another and form a linker, which connects the two surfaces of the quantum dots, so that the linker and the quantum dots form a network.

15. The method according to claim 14,
wherein step C) is carried out by means of an initiator, by means of UV radiation or thermally.

16. The method according to claim 14,
wherein the pre-linker has a carbon chain having at least 16 carbon atoms, which in each case have a phosphonate group or sulfate group as a reactive group at their end and a functional group, wherein the carbon chain is directly bonded to the surface of a quantum dot via the phosphonate group or sulfate group, and wherein the carbon chain is bonded via the functional group to a further pre-linker of an adjacent surface of a further quantum dot.

17. The method according to claim 14,
wherein the at least one pre-linker comprises a silyl chain having at least 16 Si atoms, which in each case have a phosphonate group or sulfate group as a reactive group and a functional group, wherein the silyl chain is directly bonded to the surface of a quantum dot via the phosphonate group or sulfate group, and wherein the silyl chain is bonded via the functional group to a further pre-linker of an adjacent surface of a further quantum dot.

18. A conversion element comprising
quantum dots, which are designed for wavelength conversion of radiation,
wherein the quantum dots each have a surface, wherein at least two surfaces of adjacent quantum dots have at least one linker for spacing the quantum dots, such that a network of quantum dots and linkers is formed.
